(19) United States
(12) Patent Application Publication
(10) Pub. No.: US 2026/0164760 A1
(43) Pub. Date: Jun. 11, 2026

(54) SEMICONDUCTOR DEVICE WITH IMPROVED THERMAL CONDUCTIVITY AND METHOD OF FORMING THE SAME

(71) Applicant: GlobalFoundries Singapore Pte. Ltd., Singapore (SG)

(72) Inventors: Venkata Mangathayaru BOLLAM, Singapore (SG); Yudi SETIAWAN, Singapore (SG); Qiying WONG, Singapore (SG)

(21) Appl. No.: 18/970,069

(22) Filed: Dec. 5, 2024

(51) Int. Cl. H10D 80/30; H01L 23/00; H01L 25/00; H01L 25/065

(52) U.S. Cl. CPC H10D 80/30; H10W 90/00; H10W 80/312; H10W 80/327; H10W 90/288; H10W 90/792

(57) ABSTRACT

A bonded semiconductor device includes a lower semiconductor device, an upper semiconductor device face bonded to the lower semiconductor device, and a nanopillar structure in an insulation layer of at least one of the lower semiconductor device and the upper semiconductor device, the nanopillar structure comprising a base layer and a plurality of nanopillars that contact the base layer. The nanopillar structure is electrically isolated from conductive structures of the lower semiconductor device and the upper semiconductor device.

### BACKGROUND

Heat dissipation is an important aspect in the design of semiconductor devices. Power used by semiconductors creates heat, which must be removed from the device, but how to do this efficiently is a growing challenge. The challenge is increasing as semiconductor devices become more highly integrated, handle higher amounts of power, and is especially acute for three-dimensional integrated circuits in which two or more chips are stacked on one another.

Interlayer dielectric materials tend to have low thermal conductivity. For example, silicon dioxide has a thermal conductivity of around 1 W/mK, which limits the extent to which heat generated in the active layer of the chip can dissipate. When two chips are stacked and one of the chips retains a bulk substrate material, the active layer of that chip is thermally bounded by the substrate material on one side and two stacks of interlayer dielectric material on the other side. This can lead to excessive heat build-up at the active layer, limiting the performance of the chip and possibly leading to errors or failure.

### SUMMARY

Embodiments of the present application relate to a bonded semiconductor device and a method for forming a bonded semiconductor device.

In an embodiment, a bonded semiconductor device includes a lower semiconductor device, an upper semiconductor device face bonded to the lower semiconductor device, and a nanopillar structure in an insulation layer of at least one of the lower semiconductor device and the upper semiconductor device, the nanopillar structure comprising a base layer including a plurality of nanopillars that contact the base layer, wherein the nanopillar structure is electrically isolated from conductive structures of the lower semiconductor device and the upper semiconductor device.

In an embodiment, a bonded semiconductor device includes a bonded semiconductor device including a lower semiconductor device, an upper semiconductor device face bonded to the lower semiconductor device, a first nanopillar structure in a bonding insulation layer of the lower semiconductor device, and a second nanopillar structure in a bonding insulation layer of the upper semiconductor device, the first and second nanopillar structures each comprising a base layer including a plurality of nanopillars that contact the base layer, wherein first and second nanopillar structures are electrically isolated from conductive structures of the lower semiconductor device and the upper semiconductor device.

In an embodiment, a method for forming a bonded semiconductor device includes forming a first nanopillar structure in a bonding insulation layer of a lower semiconductor device, the first nanopillar structure including a first base layer and a plurality of nanopillars that contact the first base layer, forming a second nanopillar structure in a bonding insulation layer of an upper semiconductor device, the second nanopillar structure including a second base layer including a plurality of nanopillars that contact the second base layer, and face bonding the upper semiconductor device to the lower semiconductor device, wherein first and second nanopillar structures are electrically isolated from conductive structures of the lower semiconductor device and the upper semiconductor device.

### BRIEF DESCRIPTION OF THE DRAWINGS

FIG. 1 illustrates an embodiment of a bonded semiconductor device with nanopillar structures.

FIG. 2 illustrates another embodiment of a bonded semiconductor device with nanopillar structures.

FIGS. 3A to 3E illustrate an embodiment of a method for forming a bonded semiconductor device with nanopillar structures.

FIG. 4A to 4E illustrate another embodiment of a method for forming a bonded semiconductor device with nanopillar structures.

### DETAILED DESCRIPTION

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all. As used herein, the term “about” refers to dimensions that are within typical engineering tolerances, e.g. plus or minus 10%. Thus, for example, when a structure is referred to as having a dimension of about 1 micron, the actual dimension of that structure may vary from 0.9 to 1.1 microns.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured. The figures are not drawn to scale, and features are enlarged or diminished for visual clarity.

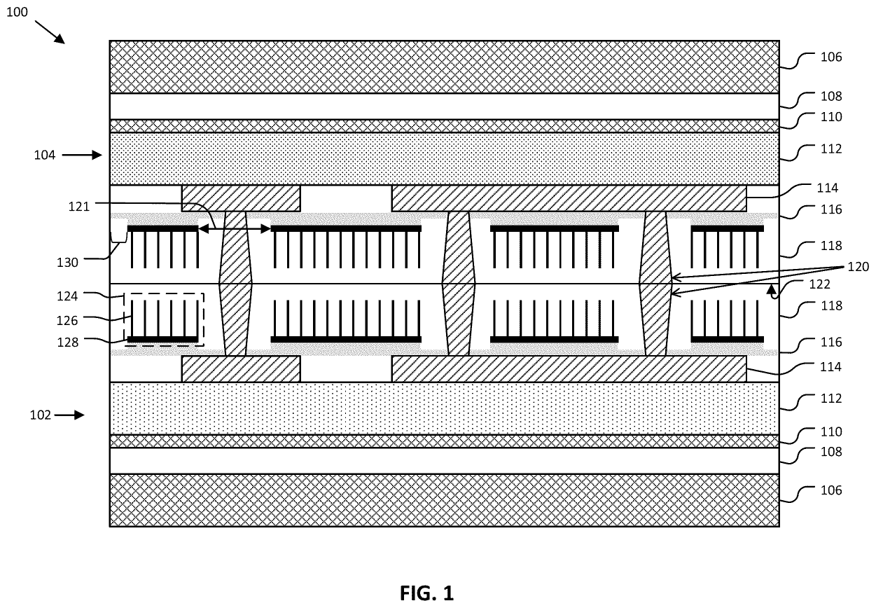

FIG. 1 illustrates an embodiment of a bonded semiconductor device 100 comprising a lower semiconductor device 102 that is face bonded to an upper semiconductor device 104. In the embodiment of FIG. 1, each of the lower and upper semiconductor devices 102 and 104 comprise a silicon on insulator (SOI) substrate. The SOI substrates include a bulk semiconductor layer 106, a buried oxide (BOX) layer 108, and a semiconductor device layer 110.

The semiconductor substrates are not limited to being SOI substrates. One or both of the substrates may be another type such as a silicon germanium substrate, a silicon bulk substrate, or another substrate as known in the art. In addition, the upper and lower semiconductor devices 102 and 104 may have different semiconductor materials from one another. For example, the lower semiconductor device 102 may comprise a silicon germanium substrate and the upper semiconductor device 104 may comprise a SOI substrate. Other variations are possible.

The SOI substrates of FIG. 1 may include active regions on which active devices are formed. The active regions include active components or circuits, such as conductive features, implantation regions, resistors, capacitors, and other semiconductor elements, e.g., transistors, diodes, etc. In some embodiments, the active regions may be bounded by shallow trench isolation (STI) structures (not shown) at sides of the active regions.

A plurality of front end of line (FEOL) and back end of line (BEOL) structures are present in a FEOL/BEOL layer 112. The FEOL structures may include active components or circuits, such as conductive features, implantation regions, resistors, capacitors, and other semiconductor elements, e.g., transistors, diodes, memory devices, etc. that are formed using front-end-of-line (FEOL) processes. The BEOL structures may include metal interconnect structures of metal levels M1 to Mn (where n is an integer greater than one), vias extending between the metal levels, and BEOL devices such as capacitors and resistors.

Top metal layer 114 is disposed over the FEOL/BEOL layer 112. The top metal layer 114 may comprise metal lines which are thicker than metal lines of the FEOL/BEOL layer 112. The metal of top metal layer 114 and BEOL metal layers may be a typical interconnect metal such as tungsten, copper or aluminum.

The lower semiconductor device 102 is face bonded to the upper device 104 at bond interface 122. Bonding vias 120, which are through oxide vias (TOVs) in the example of FIG. 1, provide electrical connections between the lower semiconductor device 102 and the upper device 104. In some embodiments, bond pads (not shown) may be present at the bond interface 122 in addition to bonding vias 120. Bonding vias 120 may comprise a metal such as copper, as well as a liner (not shown) such as a nitride material.

A nitride layer 116 is disposed over top metal layer 114. The nitride layer 116 may comprise an insulating nitride material such as silicon nitride or aluminum nitride. The thickness of nitride layer 116 may be typical for an insulating nitride layer, e.g. about 50 to 100 nanometers. One or more nanopillar structures 124 may be located on the surface of nitride layer 116.

A nanopillar structure 124 includes a base layer 128 that extends laterally and a plurality of nanopillars 126 that extend vertically from the base layer 128 with respect to the perspective in FIG. 1. Accordingly, the nanopillars 126 may be orthogonal to the base layer 128. The base layer 128 may comprise a metal material, which may be a metal or metal nitride, for example. Examples of metal materials that may be present in base layer 128 include one or both of tantalum and tantalum nitride, or one or both of titanium and titanium nitride. Nitrides may enhance compatibility with the underlying nitride layer 116, and metals may enhance compatibility with a metal material of the nanopillars 126 that extend from the base layer 128. Examples of metal materials of the nanopillars 126 include tantalum, tungsten and copper.

The shape of nanopillars 126 is not specifically restricted. For example, the nanopillars may have a cross-sectional shape that is circular, oval, or polygonal. The nanopillars 126 may have a width (e.g. a linear width between opposite parallel sides or a diameter) of from about 100 to 500 nm, and spaces between adjacent nanopillars 126 (e.g. the closest distance between sides of adjacent nanopillars 126) may be from about 200 to 500 nm. The height of nanopillars 126 may depend on the thickness of the bonding insulating layer 118 surrounding the nanopillars 126, and may be from about 1500 to 4000 nm, for example. The thickness of base layer 128 may be about 50 to 300 nm, for example.

The nanopillar structures 124 are electrically isolated from the bonding vias 120 by bonding insulating layer 118 in openings 121. Bonding insulating layer 118 may also provide a bond surface at the bond interface 122 between face bonded semiconductor devices 102 and 104. The bonding insulating layer 118 may comprise a silicon oxide material such as tetraethyl orthosilicate (TEOS), for example. In some embodiments, the nanopillar structures 124 are spaced apart from the bonding vias 120 by a thickness of about 2000 to 5000 nanometers of insulating material of the bonding insulating layer 118 to electrically isolate the nanopillar structures 124 from the bonding vias 120.

The thickness of each bonding insulation layer 118 may be about three to five microns (3000 to 5000 nm). In addition, the height of nanopillars 126 may be proportional to the thickness of the bonding insulating layer 118 of a semiconductor device 102/104, and in particular to a thickness of insulating layer 118 measured between a base of the nanopillars 126 (where the nanopillars 126 meet the base layer 128) and the bond interface 122. The height of nanopillars 126 may be from about 50% to 80% of the thickness of bonding insulating layer 118. Accordingly, a height of the nanopillars 126 may be from 50% to 80% of a thickness of the bonding insulation layer 118 between the base layer 128 of a nanopillar structure 124 and a bond interface 122 between the lower semiconductor device 102 and the upper semiconductor device 104. The insulating material above the nanopillars 126 may provide electrical insulation between the bonded devices, preventing electrical shorts that may occur to a nanopillar structure 124 of one device to transfer to the other device in a bonded device 100.

Typical materials that may be present in the bonding insulation layer 118 (such as silicon oxides) are thermal insulators, and may have thermal conductivity values of from 4 W/mK to below 1 W/mK. Accordingly, the bonding insulation layer 118 inhibits the flow of heat out of a bonded device 100, which limits the performance of the device 100. Embodiments of the present disclosure address this limitation by providing nanopillar structures 124 within the bonding insulation layer 118.

The nanopillar structures 124 may act as heat transfer devices (e.g. heatsinks) to transfer heat from the FEOL/BEOL layer 112 into and through the bonding insulation layer 118 in both the lateral and vertical directions. In particular, the base layer 128 can pick up heat from the underlying FEOL/BEOL layer 112 and transfer that heat to the nanopillars 126. The nanopillars 126 distribute heat in the vertical direction, which can cause a more even heat distribution throughout the bonding insulation layer 118 and reduce heat buildup below the bonding insulation layer 118, e.g. buildup around the top metal layer 114. Absent the nanopillar structures 124, the bonding insulation layer 118 traps heat in underlying layers.

The base layer 128 may distribute heat laterally across the bonded device 100, reducing hotspots that could otherwise build up near active structures such as transistors. In addition, the base layer 128 may transfer heat towards the edges of the bonded device 100 such that the heat can be removed through the edges of the device 100. In some embodiments, this heat transfer may be enhanced by thermally conductive structures which are positioned at the edges of the bonded device 100, for example thermally conductive structures which are added in a packaging operation.

Accordingly, edges of the base layer 128 may be positioned close to the edges of the device 100, except that a buffer region 130 of about one micron, or in the range of from about 500 to 1500 nanometers, may be present between the edge of the base layer 128 and the edge of the bonded device 100. The buffer region 130 may be filled with insulation material, e.g. the same insulation material as insulation layer 118. The buffer region 130 may prevent cracking from a dicing operation. In addition, the buffer region 130 may reduce the probability of an electrical short from edges of the bonded device 100. In an embodiment, a base layer 128 may extend across the entire lateral plane of a bonded device 100 except for openings 121 for bonding vias 120 and a buffer region 130 around edges of the base layer 128. The nitride layer 116 may or may not be present in the buffer region 130 in different embodiments.

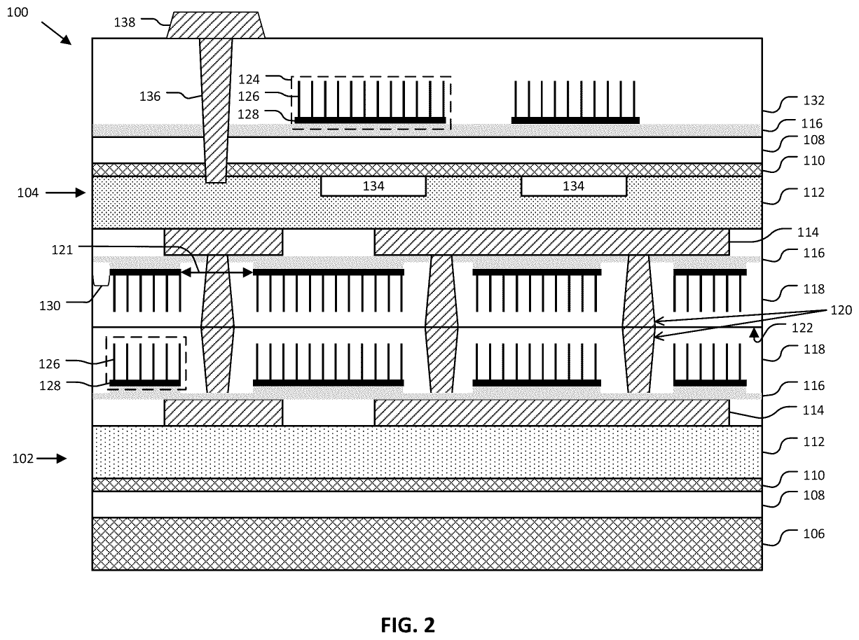

FIG. 2 illustrates another embodiment of a bonded semiconductor device 100 comprising a lower semiconductor device 102 that is bonded to an upper semiconductor device 104. In this embodiment, most or all of the bulk substrate has been removed from the backside of the upper semiconductor device 104, e.g. by at least one of a backgrinding or a reactive ion etching (RIE) process.

A backside insulation layer 132, e.g. a TEOS layer, is on the backside surface of the upper semiconductor device 104, and nanopillar structures 124 are embedded in the backside insulation layer 132, and the nanopillar structures 124 are electrically isolated from conductive structures of the lower semiconductor device 102 and the upper semiconductor device 104. A backside via 136 extends between the FEOL/BEOL layers 112 and a backside contact 138. For example, the backside via 136 may be coupled to a metal layer of a BEOL layer, and the backside contact 138 may comprise an external connection such as a metal pad or bump that transfers power or a data or clock signal to or from the bonded device 100. Various embodiments of these and similar structures are possible as known in the art.

Also shown in FIG. 2 are two transistor structures 134 located in a FEOL portion of FEOL/BEOL layer 112. In this embodiment, the nanopillar structures 124 are vertically aligned with the transistor structures 134 to effectively remove heat from the transistors without occupying the majority of backside surface of the bonded device 100. These features may be present, for example, when the bonded device 100 is an RF device to limit possible interactions between RF signals and the nanopillar structures 124. In such an embodiment, nanopillar structures 124 may be absent from the bonding insulation layer 118. In still another embodiment, the nanopillar structure 124 on the backside of the device 100 may extend across the entire lateral plane except for openings to accommodate backside vias 136 and a buffer region 130 at edges of the device.

Accordingly, in various embodiments, a bonded device 100 may include 1) nanopillar structures 124 in a backside insulation layer 132 that are selectively positioned in vertical alignment with corresponding heat sources (e.g. transistors), 2) nanopillar structures 124 in a backside insulation layer 132 that extend across a majority (greater than 50%) of the lateral plane of the device, and/or 3) at least one nanopillar structure 124 in a bonding insulation layer 118 of one or both of a lower semiconductor device 102 and an upper semiconductor device 104. In some embodiments, a nanopillar structure 124 extends across at least 60%, 70%, 75% or more of a lateral plane of one or both of a lower semiconductor device 102 and an upper semiconductor device 104. In some embodiments, a nanopillar structure 124 may extend across the entire lateral plane of a device except for spaces for vias and a buffer region 130.

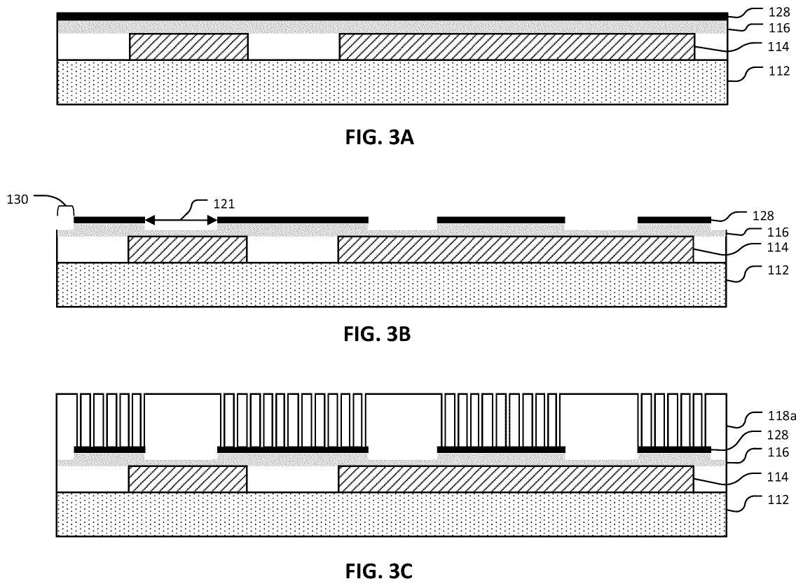

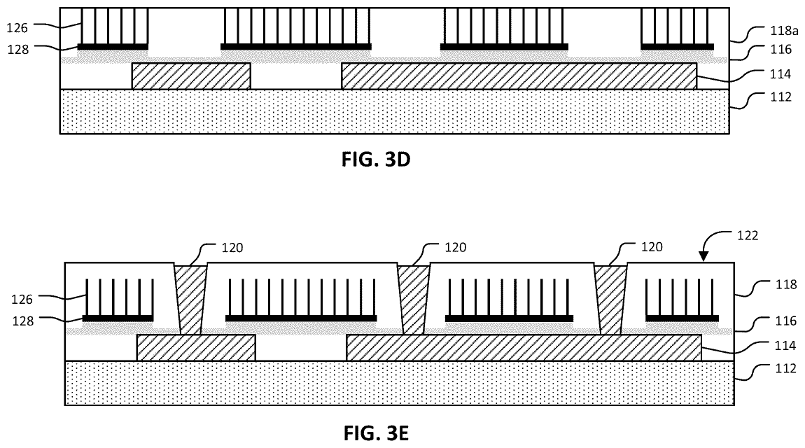

FIGS. 3A to 3E illustrate an embodiment of a method for forming a bonded semiconductor device 100. Substrate layers are omitted from these views to simplify the illustrations. The process steps illustrated by these figures may apply to either of a lower semiconductor device 102 and an upper semiconductor device 104.

After forming FEOL/BEOL layers 112 and top metal layer 114, nitride layer 116 is deposited over the top metal layer 114 using, for example, a chemical vapor deposition (CVD) process. The nitride layer 116 may comprise an insulating nitride material such as silicon nitride or aluminum nitride. Subsequently, base layer 128 is deposited over the nitride layer 116 to form the structure shown in FIG. 3A. The base layer 128 may include one or both of tantalum and tantalum nitride, or one or both of titanium and titanium nitride, and may be formed using a deposition technique appropriate for the particular material or combination of materials.

A photoresist mask (not shown) is formed over the base layer 128 and used as an etch mask to form openings 121 in the base layer 128 for vias which are formed in a later step. The etch process may result in some over-etching which can recess exposed portions of the nitride layer 116 as shown in the figures. In addition, edges of the base layer 128 may be removed by this etch process to form buffer region 130 at the edges of the base layer 128, resulting in the structure of FIG. 3B.

As seen in FIG. 3C, an insulating material (e.g. TEOS) is deposited over the etched base layer 128 and planarized using a chemical mechanical planarization (CMP) process to form a lower portion 118a of a bonding insulation layer. A photoresist mask (not shown) is formed over the planarized insulation material and used to etch openings in the insulation material for nanopillars using base layer 128 as an etch stop layer. As seen in FIG. 3D, a metal material (e.g. tungsten, copper or tantalum) is deposited to fill the openings in the insulation layer 118a, and a planarization process is performed to remove residual metal from the top surface of the insulation layer.

A second layer of insulation material (e.g. TEOS) is deposited over the insulation layer 118a to form bonding insulation layer 118 and via holes are etched through the bonding insulation layer 118 to land on a metal layer, e.g. the top metal layer 114 as seen in FIG. 3E. Subsequently, a liner material (not shown) and a via metal such as copper are deposited into the via holes and planarized to form bonding vias 120.

The via metal may be recessed from the bond interface 122 by a few angstroms to facilitate hybrid bonding. The recess may be accomplished by different processes in different embodiments. In one example, a CMP process with selective etch chemistry or a wet etch process may be used to selectively remove more via metal than insulation material. In another example, the surface may be planarized to an even height, and a thin layer of insulation material may be selectively grown on the underlying insulation material using a process such as atomic layer deposition (ALD). Accordingly, the bonding insulation layer 118 may comprise a thickness of silicon oxide (e.g. TEOS) as well as a thin layer of a different insulating material at the bond interface 122. Subsequently, a hybrid bonding process is performed by pressing the faces of two wafers together and applying heat. The heat causes the via material to expand and form a bond between the wafers. The bonded wafers are diced, resulting in the bonded semiconductor device 100 of FIG. 1.

Embodiments are not limited to these hybrid bonding techniques or the structures shown in the figures. For example, in another embodiment, bond pads may be formed over vias at the bonding interface and used to make electrical connections between the bonded devices. In other embodiments, a different hybrid bonding process may be used, or the devices may be bonded by a different technique than hybrid bonding, e.g. by using an intermediate adhesive layer.

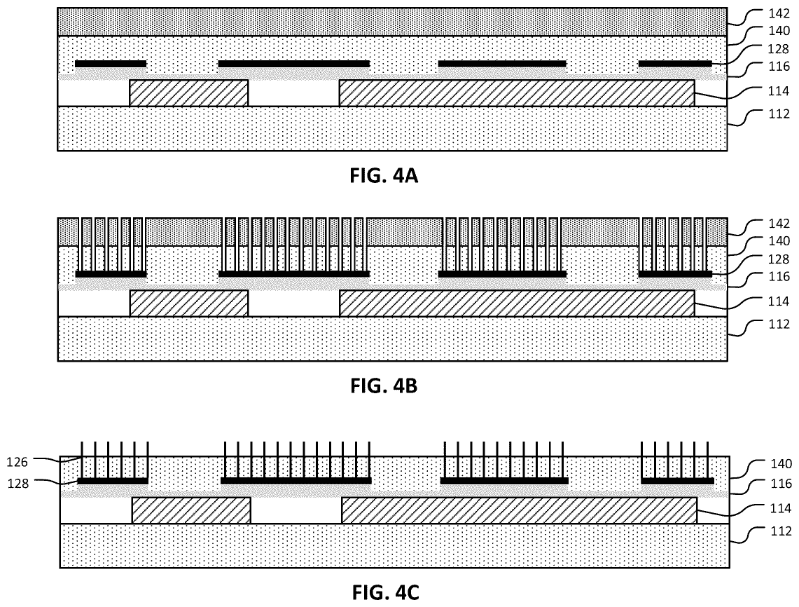

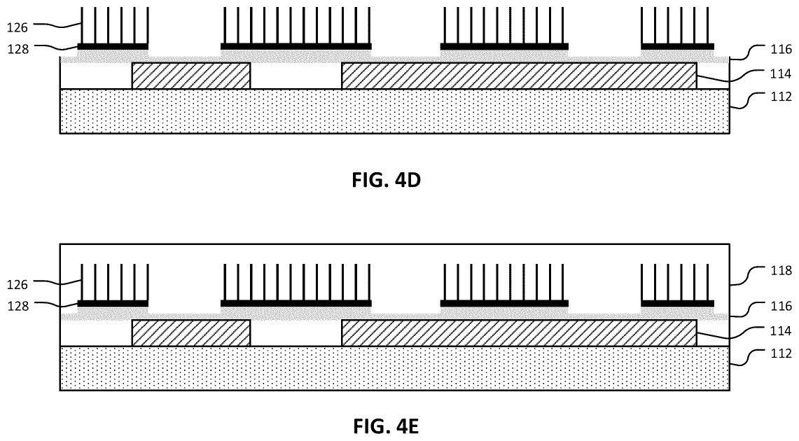

FIGS. 4A to 4E illustrate another embodiment of a method for forming a bonded semiconductor device 100. The initial steps of this embodiment may be performed in the same manner as described above with respect to FIGS. 3A and 3B, e.g. depositing a nitride layer 116 and a base layer 128 and patterning the base layer 128. As seen in FIG. 4A, a first polymer layer, e.g. a polyimide layer 140 is deposited over the base layer 128 and a second polymer layer, e.g. a photoresist layer 142 is deposited over the polyimide layer 140.

Referring to FIG. 4B, the photoresist layer 142 may be patterned with a nanopillar pattern and used as an etch mask to etch the nanopillar pattern into the polyimide layer 140 using the base layer 128 as an etch stop layer. A metal material is deposited into openings in the nanopillar pattern using, for example, a plasma vapor deposition (PVD) process. In this embodiment, the metal may be tungsten due to its compatibility with the polyimide material of polyimide layer 140.

In some embodiments, portions of the openings in the nanopillar pattern of FIG. 4B in the photoresist layer are only partially filled by the deposition process, such that nanopillars 126 extend through the entire depth of openings in the polyimide layer 140 and terminate part-way through the openings in the photoresist layer 142. Next, a stripping process is used to remove the photoresist layer 142 as well as residual tungsten on the top surface of the photoresist layer 142, resulting in the structure of FIG. 4C.

The polyimide layer 140 is in turn stripped off using, for example, a plasma stripping process as known in the art. The stripping process may expose the nanopillars 126, base layer 128 and portions of nitride layer 116 as seen in FIG. 4D. An insulation material (e.g. a TEOS material) is then deposited over the entire surface and planarized to form bonding insulation layer 118 as seen in FIG. 4E. Subsequently, vias 120 are formed as described above with respect to FIG. 3E, additional processes may performed to prepare the device for bonding, and a lower semiconductor device 102 is bonded to an upper semiconductor device 104 resulting in the bonded device 100 of FIG. 1.

Similar processes may be performed to form the backside nanopillar structures 124 of the embodiment of FIG. 2. For example, a damascene process may be performed as described with respect to FIGS. 3A-3E, or a polymer etch and stripping process may be performed as described with respect to FIGS. 4A-4E, except backside vias are formed in place of bonding vias 120 and the process may be performed on the backside of the bonded device 100 after a wafer comprising the lower semiconductor device 102 is bonded to a wafer comprising the upper semiconductor device 104.

Embodiments of the present disclosure provide significant advantages to a bonded semiconductor device 100. Face bonded devices suffer from heat buildup, and nanopillar structures 124 can alleviate that heat buildup by transferring heat laterally through a base layer 128 and vertically through nanopillars 126. The lateral and vertical distribution of heat may result in a more even heat distribution throughout a bonded device 100, and can facilitate transfer heat out of the device in both vertical and lateral directions. The nanopillar structures 124 can be formed with conventional materials such as metals and metal nitrides in a configuration that minimizes the risk of electrical shorts. These and other advantages will be apparent to a person of skill in the art from the embodiments described by the present disclosure.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A bonded semiconductor device comprising:
a lower semiconductor device;
an upper semiconductor device face bonded to the lower semiconductor device; and
a nanopillar structure in an insulation layer of at least one of the lower semiconductor device and the upper semiconductor device, the nanopillar structure comprising a base layer and a plurality of nanopillars that contact the base layer,
wherein the nanopillar structure is electrically isolated from conductive structures of the lower semiconductor device and the upper semiconductor device.

2. The bonded semiconductor device of claim 1, wherein the nanopillars comprise at least one of copper, tungsten and tantalum.

3. The bonded semiconductor device of claim 1, wherein the base layer comprises at least one of tantalum, tantalum nitride, titanium and titanium nitride.

4. The bonded semiconductor device of claim 1, wherein a width of the nanopillars is from about 100 to 500 nanometers, and a spacing between adjacent nanopillars is from about 200 to 500 nanometers.

5. The bonded semiconductor device of claim 1, wherein the nanopillar structure extends across a majority of a lateral plane of the at least one of the lower semiconductor device and the upper semiconductor device.

6. The bonded semiconductor device of claim 5, further comprising a buffer region around an edge of the at least one of the lower semiconductor device and the upper semiconductor device, wherein the nanopillar structure terminates at the buffer region.

7. The bonded semiconductor device of claim 1, wherein the insulation layer is a bonding insulation layer adjacent to a bond interface between the lower semiconductor device and the upper semiconductor device.

8. The bonded semiconductor device of claim 7, further comprising a plurality of bonding vias that extend through the bonding insulation layer, wherein the nanopillar structure includes a plurality of openings around the plurality of bonding vias.

9. The bonded semiconductor device of claim 1, further comprising a second nanopillar structure located in a bonding insulation layer of the upper semiconductor device,
wherein the insulation layer is a bonding insulation layer of the lower semiconductor device.

10. The bonded semiconductor device of claim 1, wherein a height of the nanopillars is about 1500 to 4000 nanometers.

11. The bonded semiconductor device of claim 10, wherein the height of the nanopillars is from 50 to 80% of a thickness of the insulation layer between the base layer of the nanopillar structure and a bond interface between the lower semiconductor device and the upper semiconductor device.

12. The bonded semiconductor device of claim 1, further comprising a nitride layer that contacts the base layer.

13. The bonded semiconductor device of claim 1, wherein the insulation layer is a backside insulation layer of the upper semiconductor device.

14. A bonded semiconductor device comprising:
a lower semiconductor device;
an upper semiconductor device face bonded to the lower semiconductor device;
a first nanopillar structure in a bonding insulation layer of the lower semiconductor device; and
a second nanopillar structure in a bonding insulation layer of the upper semiconductor device, the first and second nanopillar structures each comprising a base layer and a plurality of nanopillars that contact the base layer,
wherein first and second nanopillar structures are electrically isolated from conductive structures of the lower semiconductor device and the upper semiconductor device.

15. The bonded semiconductor device of claim 14, wherein the nanopillars comprise at least one of copper, tungsten and tantalum and the base layers comprise at least one of tantalum, tantalum nitride, titanium and titanium nitride.

16. The bonded semiconductor device of claim 14, wherein a width of the nanopillars is from about 100 to 500 nanometers, and a spacing between adjacent nanopillars of each nanopillar structure is from about 200 to 500 nanometers.

17. The bonded semiconductor device of claim 14, wherein a height of the nanopillars is about 1500 to 4000 nanometers.

18. The bonded semiconductor device of claim 14, wherein the first nanopillar structure extends across a majority of a lateral plane of the lower semiconductor device and the second nanopillar structure extends across a majority of a lateral plane of the upper semiconductor device.

19. The bonded semiconductor device of claim 18, further comprising a first buffer region around an edge of the lower semiconductor device and a second buffer region around an edge of the upper semiconductor device, wherein the first nanopillar structure terminates at the first buffer region and the second nanopillar structure terminates at the second buffer region.

20. A method for forming a bonded semiconductor device, the method comprising:
forming a first nanopillar structure in a bonding insulation layer of a lower semiconductor device, the first nanopillar structure including a first base layer including a plurality of metal nanopillars that contact the first base layer;
forming a second nanopillar structure in a bonding insulation layer of an upper semiconductor device, the second nanopillar structure including a second base layer and a plurality of nanopillars that contact the second base layer; and
face bonding the upper semiconductor device to the lower semiconductor device,
wherein first and second nanopillar structures are electrically isolated from conductive structures of the lower semiconductor device and the upper semiconductor device.
